(19) United States
(12) Patent Application Publication
(10) Pub. No.: US 2021/0020406 A1
(43) Pub. Date: Jan. 21, 2021

(54) PLASMA PROCESSING APPARATUS

(71) Applicant: Tokyo Electron Limited, Tokyo (JP)

(72) Inventor: Kazushi KANEKO, Kurokawa-gun (JP)

(73) Assignee: Tokyo Electron Limited, Tokyo (JP)

(21) Appl. No.: 16/923,386

(22) Filed: Jul. 8, 2020

(30) Foreign Application Priority Data
Jul. 19, 2019 (JP) 2019-133858

(51) Int. Cl. H01J 37/32

(52) U.S. Cl. CPC H01J 37/3222; H01J 37/32229

(57) ABSTRACT

A plasma processing apparatus according to an exemplary embodiment includes a chamber, a microwave generator, an antenna, and a coaxial waveguide. The antenna is configured to radiate a microwave into the chamber. The coaxial waveguide is configured to cause a microwave output from the microwave generator to propagate between the microwave generator and the antenna. A diameter d of an outer circumferential surface of an inner conductor and a diameter D of an inner circumferential surface of an outer conductor of each of one or more coaxial tubes configuring the coaxial waveguide satisfy D+d≤76.3 mm, d≥21 mm, and D≥3.71×(R+1)/log₁₀(R). R is D/d.

### CROSS-REFERENCE TO RELATED APPLICATIONS

This application is based on and claims the benefit of priority from Japanese Patent Application No. 2019-133858 filed on Jul. 19, 2019, the entire contents of which are incorporated herein by reference.

### TECHNICAL FIELD

An exemplary embodiment of the present disclosure relates to a plasma processing apparatus.

### BACKGROUND

A plasma processing apparatus is used for plasma processing on a substrate. Japanese Patent Application Laid-Open Publication No. 2018-78010 (hereinafter, referred to as “Patent Literature 1”) discloses a plasma processing apparatus that generates plasma by using a microwave. The plasma processing apparatus disclosed in Patent Literature 1 includes a chamber, an antenna, and a microwave generator. The antenna radiates a microwave into the chamber. The microwave generator and the antenna are connected to each other via a rectangular waveguide tube and a coaxial tube. A converter that converts a mode of a microwave is necessary between the rectangular waveguide tube and the coaxial tube.

### SUMMARY

In one exemplary embodiment, a plasma processing apparatus is provided. The plasma processing apparatus includes a chamber, a microwave generator, an antenna, and a coaxial waveguide. The antenna is configured to radiate a microwave into the chamber. The coaxial waveguide is configured to cause a microwave output from the microwave generator to propagate between the microwave generator and the antenna. A diameter d of an outer circumferential surface of an inner conductor and a diameter D of an inner circumferential surface of an outer conductor of each of one or more coaxial tubes configuring the coaxial waveguide satisfy D+d≤76.3 mm, d≥21 mm, and D≥3.71×(R+1)/log₁₀(R). R is D/d.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a diagram schematically illustrating a plasma processing apparatus according to one exemplary embodiment.

FIG. 2 is a diagram illustrating a configuration of a microwave generator of the plasma processing apparatus according to the exemplary embodiment along with a coaxial waveguide and an antenna.

FIG. 3 is a diagram illustrating a microwave generation principle in a waveform generator of the plasma processing apparatus according to the exemplary embodiment.

FIG. 4 is a sectional view of one or more coaxial tubes in the plasma processing apparatus according to the exemplary embodiment.

FIG. 5 is a diagram illustrating a condition to be satisfied by a diameter of an outer circumferential surface of an inner conductor and a diameter of an inner circumferential surface of an outer conductor of the one or more coaxial tubes of the coaxial waveguide in the plasma processing apparatus according to the exemplary embodiment.

### DETAILED DESCRIPTION

Hereinafter, various exemplary embodiments will be described.

In one exemplary embodiment, there is provided a plasma processing apparatus. The plasma processing apparatus includes a chamber, a microwave generator, an antenna, and a coaxial waveguide. The antenna is configured to radiate a microwave into the chamber. The coaxial waveguide is configured to cause a microwave output from the microwave generator to propagate between the microwave generator and the antenna. A diameter d of an outer circumferential surface of an inner conductor and a diameter D of an inner circumferential surface of an outer conductor of each of one or more coaxial tubes configuring the coaxial waveguide satisfy the following Equations (1), (2), and (3).

$$\begin{matrix}D + d \leq 76.3 [ mm ] & ( 1 ) \\ d \geq 21 [ mm ] & ( 2 ) \\ D \geq 3.71 \times \frac{( R + 1 )}{{log}_{10} ( R )} & ( 3 )\end{matrix}$$

R in Equation (3) is D/d.

In the plasma processing apparatus of the embodiment, the microwave generator and the antenna are connected to each other via the coaxial waveguide. Therefore, a converter that converts a mode of a microwave is not necessary between a waveguide tube and a coaxial tube. Therefore, according to the plasma processing apparatus, it is possible to reduce a space in which a waveguide is disposed between the microwave generator and the antenna. Since the microwave generator and the antenna are connected to each other via the coaxial waveguide, it is possible to reduce non-uniformity of an electric field distribution of a microwave supplied to the antenna. When D+d≤76.3 mm is satisfied, the occurrence of a higher-order mode having a frequency higher than 2500 MHz is suppressed. When d≥21 mm is satisfied, allowable power of 4 kW or more can be obtained. When D≥3.71×(R+1)/log₁₀(R) is satisfied, an attenuation rate of a microwave per unit length in the coaxial waveguide is equal to or less than 1%. When the Equations (1), (2), and (3) are satisfied, discharge power of 10 kW or more can be obtained.

In one exemplary embodiment, the microwave generator and the antenna are connected to each other via only the coaxial waveguide.

In one exemplary embodiment, a characteristic impedance of the coaxial waveguide may be a value other than 50Ω.

Hereinafter, various exemplary embodiments will be described in detail with reference to the drawings. In the drawing, the same or equivalent portions are denoted by the same reference symbols.

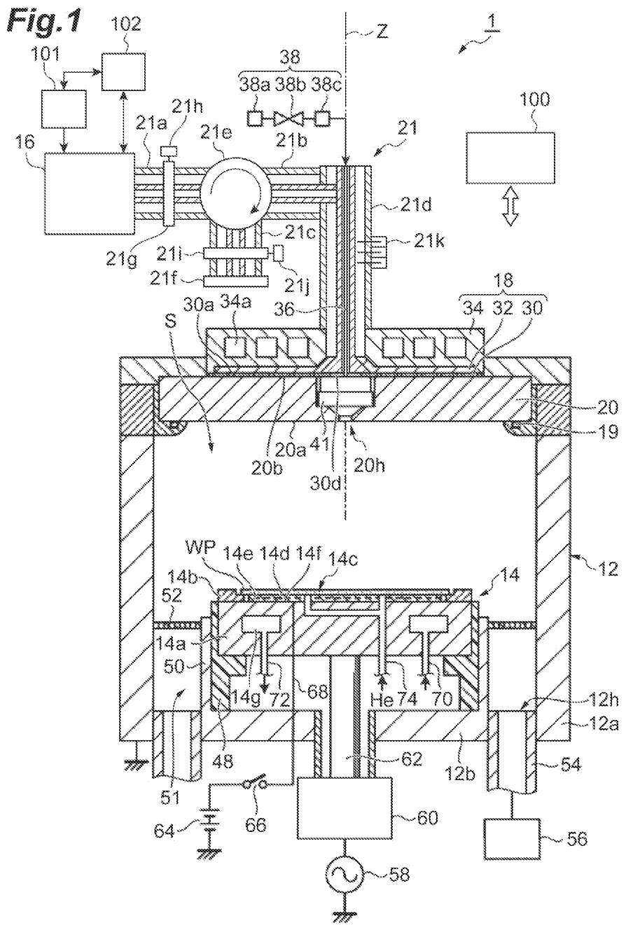

FIG. 1 is a diagram schematically illustrating a plasma processing apparatus according to one exemplary embodiment. A plasma processing apparatus 1 illustrated in FIG. 1 includes a chamber 12, a microwave generator 16, an antenna 18, and a coaxial waveguide 21.

The chamber 12 provides a processing space S at the inside thereof. The chamber 12 includes a side wall 12a and a bottom portion 12b. The side wall 12a is formed in a substantially cylindrical shape. A central axis of the side wall 12a substantially coincides with an axis Z that extends in a vertical direction. The bottom portion 12b is provided on a lower end side of the side wall 12a. An exhaust hole 12h for exhaust is provided in the bottom portion 12b. An upper end of the side wall 12a provides an opening.

The plasma processing apparatus 1 may be further provided with a dielectric window 20. The dielectric window 20 is provided over the upper end of the side wall 12a. The dielectric window 20 has a lower surface 20a. The lower surface 20a defines the processing space S from above. The dielectric window 20 closes the opening in the upper end of the side wall 12a. A sealing member 19 such as an O-ring may be interposed between the dielectric window 20 and the upper end of the side wall 12a.

The plasma processing apparatus 1 may be further provided with a stage 14. The stage 14 is provided in the processing space S. The stage 14 faces the dielectric window 20 in the vertical direction. The stage 14 is provided such that the processing space S is provided between the dielectric window 20 and the stage 14. The stage 14 is configured to support a workpiece WP (for example, a wafer) mounted thereon. The workpiece WP may have, for example, a disc shape.

In an embodiment, the stage 14 may include a base 14a and an electrostatic chuck 14c. The base 14a is made of a conductive material such as aluminum. The base 14a has a substantially disc shape. A central axis of the base 14a substantially coincides with the axis Z. The base 14a is supported by a cylindrical support 48. The cylindrical support 48 extends upwards from the bottom portion 12b. The cylindrical support 48 is made of an insulating material. A cylindrical support 50 is provided along an outer circumference of the cylindrical support 48. The cylindrical support 50 extends upwards from the bottom portion 12b of the chamber 12. The cylindrical support 50 is conductive. An annular exhaust path 51 is formed between the cylindrical support 50 and the side wall 12a.

A baffle plate 52 is provided in the exhaust path 51. The baffle plate 52 has an annular shape. A plurality of through-holes, which pass through the baffle plate 52 in a plate thickness direction, are formed in the baffle plate 52. The above-described exhaust hole 12h is provided below the baffle plate 52. An exhaust device 56 is connected to the exhaust hole 12h through an exhaust pipe 54. The exhaust device 56 may include an automatic pressure control valve, and a vacuum pump such as a turbo-molecular pump. A pressure in the processing space S may be reduced to a desired vacuum degree by the exhaust device 56.

The base 14a also functions as a radio frequency electrode. A radio frequency power supply 58 is electrically connected to the base 14a through a feeding rod 62 and a matching unit 60. The radio frequency power supply 58 generates radio frequency power. The radio frequency power generated by the radio frequency power supply 58 has a frequency suitable to control ion energy which is attracted to the workpiece WP. The frequency is, for example, 13.56 MHz.

The matching unit 60 has a matcher configured to attain matching between output impedance of the radio frequency power supply 58, and impedance mainly on a load side such as an electrode, plasma, and the chamber 12. The matcher may include a blocking capacitor for self-bias generation.

The electrostatic chuck 14c is provided on the base 14a. The electrostatic chuck 14c may have a substantially disc shape. A central axis of the electrostatic chuck 14c substantially coincides with the axis Z. The electrostatic chuck 14c is configured to hold the workpiece WP by an electrostatic attraction force. The electrostatic chuck 14c may include an electrode 14d, an insulating film 14e, and an insulating film 14f. The electrode 14d is configured with a conductive film, and is provided between the insulating film 14e and the insulating film 14f. A DC power supply 64 is electrically connected to the electrode 14d through a switch 66 and a covered wire 68. When a DC voltage from the DC power supply 64 is applied to the electrode 14d, an electrostatic attraction force is generated between the electrostatic chuck 14c and the workpiece WP. The electrostatic chuck 14c holds the workpiece WP by the generated electrostatic attraction force. A focus ring 14b is provided on the base 14a. The workpiece WP is disposed in a region surrounded by focus ring 14b on the electrostatic chuck 14c.

A refrigerant chamber 14g is provided at the inside of the base 14a. For example, the refrigerant chamber 14g extends around the axis Z. A refrigerant is supplied into the refrigerant chamber 14g from a chiller unit through a pipe 70. The refrigerant, which is supplied into the refrigerant chamber 14g, returns to the chiller unit through a pipe 72. A temperature of the refrigerant is controlled by the chiller unit, and thus a temperature of the electrostatic chuck 14c and a temperature of the workpiece WP are controlled.

A gas supply line 74 is formed in the stage 14. The gas supply line 74 is provided to supply a heat transfer gas, for example, a He gas to a gap between an upper surface of the electrostatic chuck 14c and a rear surface of the workpiece WP.

The plasma processing apparatus 1 may be further provided with a gas supply system 38. The gas supply system 38 is provided to introduce a process gas into the processing space S. In an embodiment, the gas supply system 38 introduces the process gas into the processing space S through a conduit 36 and an injector 41. The process gas is a gas used to process the workpiece WP. The gas supply system 38 may include a gas source 38a, a valve 38b, and a flow rate controller 38c. The gas source 38a is a gas source of the process gas. The valve 38b is, for example, an opening/closing valve, and is configured to switch supply and supply stoppage of the process gas from the gas source 38a. For example, the flow rate controller 38c is a mass flow controller, and is configured to adjust a flow rate of the process gas from the gas source 38a. The gas supply system 38 is connected to the conduit 36. The gas supply system 38 outputs the process gas to the conduit 36.

The injector 41 is disposed in a space formed inside the dielectric window 20. The injector 41 outputs a gas from the conduit 36 to a hole 20h formed in the dielectric window 20. The gas output to the hole 20h is supplied to the processing space S.

The microwave generator 16 is configured to generate a microwave for exciting a gas supplied into the chamber 12. The microwave generator 16 is connected to the antenna 18 through the coaxial waveguide 21. The coaxial waveguide 21 is configured to cause a microwave output from the microwave generator 16 to propagate between the microwave generator 16 and the antenna 18. The antenna 18 is provided on a surface 20b of the dielectric window 20 on the opposite side to the lower surface 20a. The antenna 18 is configured to radiate a microwave into the chamber 12 (that is, the processing space S) through the dielectric window 20.

The microwave radiated into the processing space S from the antenna 18 through the dielectric window 20 excites a process gas in the chamber 12. Consequently, plasma is generated from the process gas in the processing space S. The workpiece WP is processed by a chemical species such as an ion and/or a radical from the generated plasma.

The plasma processing apparatus 1 further includes a controller 100. The controller 100 collectively controls respective units of the plasma processing apparatus 1. The controller 100 may include a processor such as a CPU, a user interface, and a storage unit.

The processor executes a program and a process recipe stored in the storage unit so as to collectively control respective units such as the microwave generator 16, the stage 14, the gas supply system 38, and the exhaust device 56.

The user interface includes, for example, a keyboard or a touch panel with which a process manager performs a command input operation and the like so as to manage the plasma processing apparatus 1, and a display that visually displays an operation situation of the plasma processing apparatus 1.

The storage unit stores, for example, control programs (software) for realizing various kinds of processing executed by the plasma processing apparatus 1 by a control of the processor, and a process recipe including process condition data and the like. The processor calls various kinds of control programs from the storage unit and executes the control programs in correspondence with necessity including an instruction from the user interface. Desired processing is executed in the plasma processing apparatus 1 under the control of the processor.

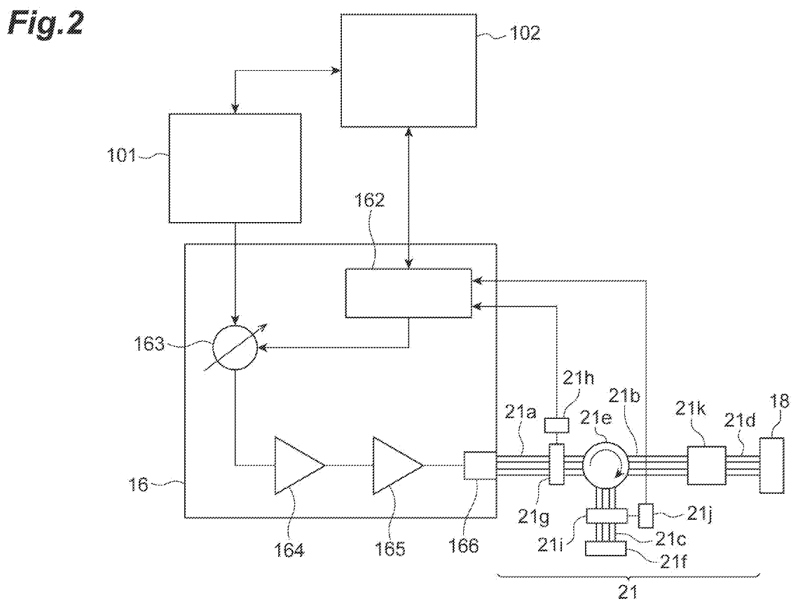

Hereinafter, with reference to FIG. 2 along with FIG. 1, the microwave generator 16, the antenna 18, and the coaxial waveguide 21 will be described in detail. FIG. 2 is a diagram illustrating a configuration of the microwave generator of the plasma processing apparatus according to the exemplary embodiment along with the coaxial waveguide and the antenna.

In an embodiment, the plasma processing apparatus 1 is configured to variably adjust a frequency, power, and a bandwidth of a microwave output from the microwave generator 16. The plasma processing apparatus 1 is able to set, for example, a bandwidth of a microwave to substantially 0 to generate a microwave having a single frequency. The plasma processing apparatus 1 is able to generate a microwave having a bandwidth including a plurality of frequency components. The plurality of frequency components may have the same power as each other. Alternatively, only a center frequency component in a band may have power higher than power of remaining frequency components. In an example, the plasma processing apparatus 1 may adjust power of a microwave within a range of 0 W to 5000 W. The plasma processing apparatus 1 may adjust a frequency or a center frequency of a microwave within a range of 2400 MHz to 2500 MHz. The plasma processing apparatus 1 may adjust a bandwidth of a microwave within a range of 0 MHz to 400 MHz. The plasma processing apparatus 1 may adjust a pitch (carrier pitch) of frequencies of a plurality of frequency components of a microwave in a band within a range of 0 to 25 kHz.

As illustrated in FIG. 2, the microwave generator 16 is connected to a waveform generator 101 and a controller 102. The waveform generator 101 generates a microwave having a center frequency and a bandwidth respectively corresponding to a set frequency and a set bandwidth designated by the controller 102. The set frequency and the set bandwidth are designated for the controller 102 from the controller 100 on the basis of a recipe.

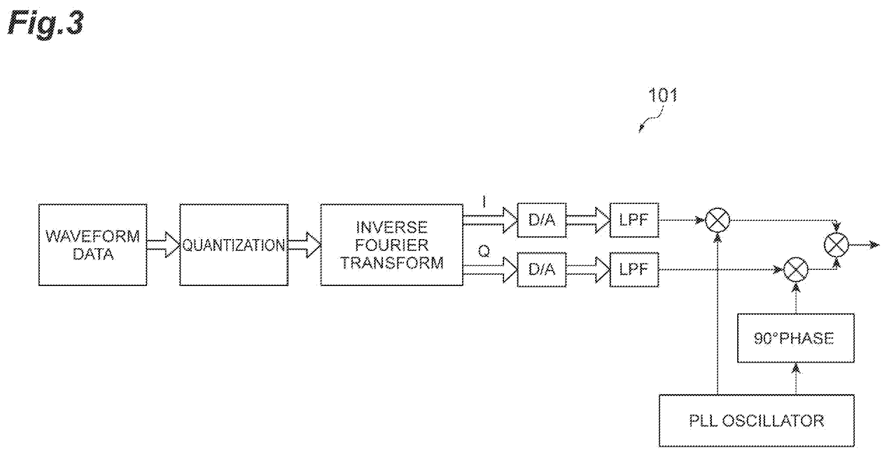

FIG. 3 is a diagram illustrating an example of a microwave generation principle in the waveform generator of the plasma processing apparatus according to the exemplary embodiment. In an embodiment, as illustrated in FIG. 3, the waveform generator 101 includes a phase locked loop (PLL) oscillator and an IQ digital modulator. The PLL oscillator causes a microwave of which a phase is synchronized with that of a reference frequency to oscillate. The IQ digital modulator is connected to the PLL oscillator. The waveform generator 101 sets a frequency of a microwave oscillating from the PLL oscillator to the set frequency designated by the controller 102. The waveform generator 101 modulates a microwave from the PLL oscillator and a microwave having a phase difference of 900 with the microwave from the PLL oscillator by using the IQ digital modulator. Consequently, the waveform generator 101 generates a microwave having a plurality of frequency components in a band or a microwave having a single frequency.

The waveform generator 101 generates a continuous signal by performing inverse discrete Fourier transform on, for example, N complex data symbols, and can thus generate a microwave having a plurality of frequency components. A method of generating the signal may be an orthogonal frequency-division multiple access (OFDMA) modulation method used for digital TV broadcasting or the like.

In an example, the waveform generator 101 has waveform data represented by a digitalized code sequence in advance. The waveform generator 101 quantizes the waveform data, and applies the inverse Fourier transform to the quantized data so as to generate I data and Q data. The waveform generator 101 applies digital/analog (D/A) conversion to each of the I data and the Q data so as to obtain two analog signals. The waveform generator 101 inputs the analog signals to a low-pass filter (LPF) through which only a low frequency component passes. The waveform generator 101 mixes the two analog signals, which are output from the LPF, with a microwave from the PLL oscillator and a microwave having a phase difference of 90° with the microwave from the PLL oscillator, respectively. The waveform generator 101 combines microwaves which are generated through the mixing with each other. Consequently, the waveform generator 101 generates a microwave having a single frequency component or a plurality of frequency components. The waveform generator 101 outputs the generated microwave to the microwave generator 16.

In an embodiment, as illustrated in FIG. 2, the microwave generator 16 includes a power controller 162, an attenuator 163, an amplifier 164, an amplifier 165, and a coupler 166.

The waveform generator 101 is connected to the attenuator 163. The attenuator 163 is a device that can change an attenuation amount (attenuation rate) according to, for example, an applied voltage value. The attenuator 163 is connected to the power controller 162. The power controller 162 may have a processor. The power controller 162 acquires a setting profile from the controller 102. The setting profile is designated for the controller 102 from the controller 100 according to set power that is specified in a recipe. The power controller 162 determines an attenuation rate (attenuation amount) of a microwave in the attenuator 163 on the basis of the acquired setting profile. The power controller 162 controls an attenuation rate (attenuation amount) of a microwave in the attenuator 163 to be the determined attenuation rate (attenuation amount) using the applied voltage value. The attenuator 163 adjusts an attenuation rate (attenuation amount) of a microwave output from the waveform generator 101 such that power of a microwave output from the microwave generator 16 is power corresponding to set power.

An output of the attenuator 163 is connected to the coupler 166 through the amplifier 164 and the amplifier 165. Each of the amplifier 164 and the amplifier 165 amplifies a microwave at a predetermined amplification rate. The coupler 166 couples a microwave output from the amplifier 165 to the coaxial waveguide 21.

As described above, the coaxial waveguide 21 is configured to cause a microwave output from the microwave generator 16 to propagate between the microwave generator 16 and the antenna 18. The microwave generator 16 and the antenna 18 may be connected to each other via only the coaxial waveguide 21.

The coaxial waveguide 21 has one or more coaxial tubes. Each of the one or more coaxial tubes has an inner conductor and an outer conductor. The inner conductor is formed in a columnar or cylindrical shape. The outer conductor is formed in a cylindrical shape, and is provided coaxially with the inner conductor outside the inner conductor. In other words, the inner conductor extends inside the outer conductor. In an embodiment, the coaxial waveguide 21 has a coaxial tube 21a, a coaxial tube 21b, a coaxial tube 21c, and a coaxial tube 21d as the one or more coaxial tubes. One end of the coaxial tube 21a is connected to the coupler 166. The other end of the coaxial tube 21a is connected to a first port of a coaxial circulator 21e. The coaxial circulator 21e has first to third ports. The coaxial circulator 21e is configured to output a microwave that is input to the first port from the second port, and to output a microwave that is input to the second port from the third port.

The second port of the coaxial circulator 21e is connected to one end of the coaxial tube 21b. The third port of the coaxial circulator 21e is connected to one end of the coaxial tube 21c. The other end of the coaxial tube 21c is connected to a dummy load 21f. The dummy load 21f receives a microwave propagating through the coaxial tube 21c, and absorbs the microwave. The dummy load 21f converts the microwave into, for example, heat.

The plasma processing apparatus 1 may further include a first coaxial directional coupler 21g, a first detector 21h, a second coaxial directional coupler 21i, and a second detector 21j. The first coaxial directional coupler 21g is provided between one end and the other end of the coaxial tube 21a. The first coaxial directional coupler 21g is configured to branch a portion of a microwave, that is, a travelling wave that is output from the microwave generator 16 and propagates through the coaxial tube 21a, and to output the portion of the travelling wave. The first detector 21h is configured to receive the portion of the travelling wave output from the first coaxial directional coupler 21g, and to detect a measured value indicating power of the travelling wave.

The second coaxial directional coupler 21i is provided between one end and the other end of the coaxial tube 21c. The second coaxial directional coupler 21i is configured to branch a portion of a microwave, that is, a reflected wave that propagates through the coaxial tube 21c, and to output the portion of the reflected wave. The second detector 21j is configured to receive the portion of the reflected wave output from the second coaxial directional coupler 21i, and to detect a measured value indicating power of the reflected wave.

The first detector 21h and the second detector 21j are connected to the power controller 162. The power controller 162 controls the attenuator 163 such that a difference between power of a travelling wave and power of a reflected wave, that is, load power (effective power) matches set power by using the measured values respectively acquired by the first detector 21h and the second detector 21j.

The other end of the coaxial tube 21b is connected to the coaxial tube 21d. A coaxial tuner 21k is connected between one end and the other end of the coaxial tube 21d. The coaxial tuner 21k is configured to adjust positions of a plurality of stubs such that impedance on the antenna 18 side matches impedance on the microwave generator 16 side.

The antenna 18 includes a slot plate 30, a dielectric plate 32, and a cooling jacket 34. The slot plate 30 is provided on the surface 20b of the dielectric window 20. The slot plate 30 is made of conductive metal. The slot plate 30 has a substantially disc shape. A central axis of the slot plate 30 substantially coincides with the axis Z. The slot plate 30 is provided with a plurality of slot holes 30a. The plurality of slot holes 30a configure a plurality of slot pairs in an example. Each of the plurality of slot pairs includes two slot holes 30a that extend in directions intersecting each other and have a substantially long hole shape. The plurality of slot pairs are arranged along one or more concentric circles around the axis Z. A through-hole 30d through which the conduit 36 is passable is provided at the center of the slot plate 30.

The dielectric plate 32 is provided on the slot plate 30. The dielectric plate 32 is made of a dielectric material such as quartz. The dielectric plate 32 has a substantially disc shape. A central axis of the dielectric plate 32 substantially coincides with the axis Z. The cooling jacket 34 is provided on the dielectric plate 32. The dielectric plate 32 is provided between the cooling jacket 34 and the slot plate 30.

A surface of the cooling jacket 34 is conductive. A flow passage 34a is formed inside the cooling jacket 34. A refrigerant is supplied to the flow passage 34a. A lower end of the outer conductor of the coaxial tube 21d is connected to an upper surface of the cooling jacket 34. A lower end of the inner conductor of the coaxial tube 21d passes through a hole formed in the cooling jacket 34 and a central portion of the dielectric plate 32 and is connected to the slot plate 30.

In an embodiment, the inner conductor of the coaxial tube 21d is formed in a cylindrical shape. The conduit 36 passes through an inner hole of the inner conductor of the coaxial tube 21d. As described above, the through-hole 30d through which the conduit 36 is passable is provided at the center of the slot plate 30. The conduit 36 passes and extends through the inner hole of the inner conductor of the coaxial tube 21d, and is connected to the gas supply system 38. The inner conductor of the coaxial tube 21d is required to have a hollow structure since the conduit 36 extends therethrough. On the other hand, each inner conductor of the coaxial tubes 21a, 21b, and 21c other than the coaxial tube 21d among the coaxial tubes of the coaxial waveguide 21 may not have a hollow structure.

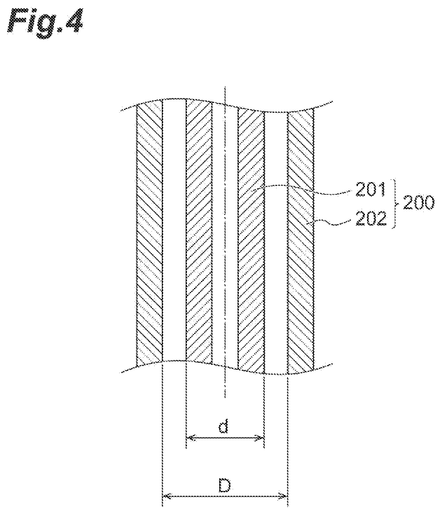

Hereinafter, reference will be made to FIG. 4. FIG. 4 is a sectional view of one or more coaxial tubes in the plasma processing apparatus according to the exemplary embodiment. As described above, the coaxial waveguide 21 has one or more coaxial tubes 200. In an embodiment, the coaxial waveguide 21 has the coaxial tubes 21a to 21d as the one or more coaxial tubes 200. As described above and illustrated in FIG. 4, each of the one or more coaxial tubes 200 has an inner conductor 201 and an outer conductor 202. A diameter d of an outer circumferential surface of the inner conductor 201 of and a diameter D of an inner circumferential surface of the outer conductor 202 of each of the one or more coaxial tubes 200 satisfy the above Equations (1), (2), and (3).

In the plasma processing apparatus 1, the microwave generator 16 and the antenna 18 are connected to each other via the coaxial waveguide 21. Therefore, a converter that converts a mode of a microwave is not necessary between a waveguide tube and a coaxial tube. Therefore, according to the plasma processing apparatus 1, it is possible to reduce a space in which a waveguide is disposed between the microwave generator 16 and the antenna 18. Since the microwave generator 16 and the antenna 18 are connected to each other via the coaxial waveguide 21, it is possible to reduce non-uniformity of an electric field distribution of a microwave supplied to the antenna 18. When D+d≤76.3 mm is satisfied, the occurrence of a higher-order mode having a frequency higher than 2500 MHz is suppressed. When d≥21 mm is satisfied, allowable power of 4 kW or more can be obtained. When D≥3.71×(R+1)/log₁₀(R) is satisfied, an attenuation rate of a microwave per unit length in the coaxial waveguide 21 is equal to or less than 1%. When the Equations (1), (2), and (3) are satisfied, discharge power of 10 kW or more can be obtained.

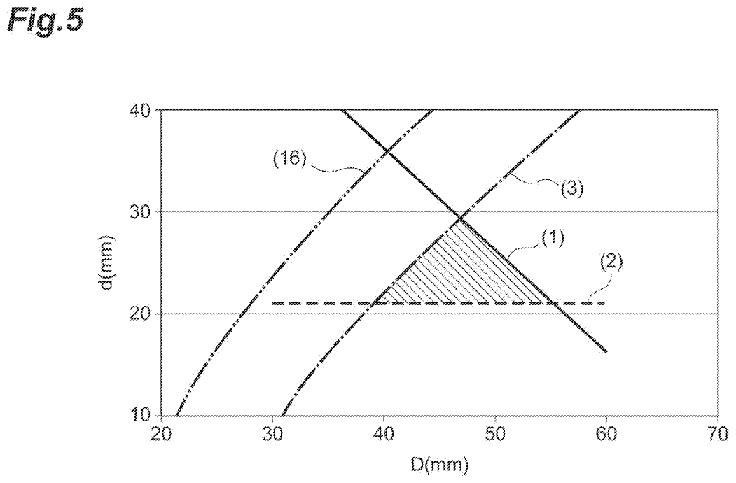

Hereinafter, reference will be made to FIG. 5. FIG. 5 is a diagram illustrating a condition to be satisfied by the diameter d of the outer circumferential surface of the inner conductor and the diameter D of the inner circumferential surface of the outer conductor of the one or more coaxial tubes of the coaxial waveguide in the plasma processing apparatus according to the exemplary embodiment. Here, a cutoff wavelength λ_{C} in the coaxial tube is expressed by the following Equation (4).

$${λ}_{C} = \frac{π}{2} ( d + D ) \qquad ( 4 )$$

According to Equation (4), the following Equation (5) is required to be satisfied in order to suppress the occurrence of a higher-order mode having a frequency higher than 2500 MHz in the coaxial tube.

$$D + d \leq \frac{C}{2500 \times {10}^{6}} \times \frac{2}{π} \qquad ( 5 )$$

In Equation (5), “C” is a light speed. Equation (1) is derived from Equation (5). In FIG. 5, a straight line indicated by (1) indicates a boundary of a range of a set of the diameter d and the diameter D satisfying the Equation (1).

Allowable power (power capacity) P_{C} of the coaxial tube is expressed by the following Equation (6).

P_{C}=0.03577×d^{1 54872} (6)

Equation (6) is an approximate equation derived from “Microwave Plasma Technology”, edited by the Institute of Electrical Engineers of Japan, Microwave Plasma Research Committee, Ohmsha, Ltd., Sep. 25, 2003, page 235, FIG. 6-8. The above Equation (2) is required to be satisfied so that allowable power defined in Equation (6) is equal to or more than 4000 W. In FIG. 5, a straight line indicated by (2) indicates a boundary of a range of a set of the diameter d and the diameter D satisfying the Equation (2).

Attenuation α_{C} [dB/m] per unit length in the coaxial tube is expressed by the following Equation (7).

$${α}_{C} = 8.686 \times \frac{( \frac{2}{d} + \frac{2}{D} ) \cdot \sqrt{\frac{F \cdot {ɛ}_{r} \cdot ρ \cdot μ}{4 π}}}{276 \times {log}_{10} \frac{D}{d}} = k \cdot \frac{( \frac{1}{d} + \frac{1}{D} )}{{log}_{10} \frac{D}{d}} = k \cdot \frac{( R + 1 )}{D \cdot {log}_{10} ( R )} \qquad ( 7 )$$

The Equation (7) is derived from the university course “Microwave Engineering”, Ohmsha Ltd., Mar. 10, 1980, 1st edition, 14th impression, page 16, Equation 33. Here, F is a frequency of a microwave, εᵣ is a relative permittivity of a medium between the inner conductor and the outer conductor of the coaxial tube, ρ is a conductivity of the inner conductor and the outer conductor of the coaxial tube, and μ is a permeability of the medium between the inner conductor and the outer conductor of the coaxial tube.

An attenuation rate α [%/m] of power per unit length in the coaxial tube is expressed by the following Equation (8).

$$α = \frac{P 1 - P 2}{P 1} = 1 - t \qquad ( 8 )$$

In Equation (8), P1 is power at one end of the coaxial tube in the unit length, P2 is power at the other end thereof in the unit length, and P1>P2. In Equation (8), t is P2/P1, and is a pass rate [%/m] of power per unit length in the coaxial tube. Therefore, a relationship between ac [dB/m] and t [%/m] is expressed by the following Equation (9).

$${α}_{C} = 10 \times {log}_{10} \frac{P 2}{P 1} = 10 \times {log}_{10} ( t ) \qquad ( 9 )$$

The following Equation (10) is derived from Equation (9).

$$t = {10}^{\frac{{α}_{C}}{10}} \qquad ( 10 )$$

Equation (10) is assigned to Equation (8), and thus the following Equation (11) is derived.

$$\frac{{α}_{C}}{10} = {log}_{10} ( 1 - α ) \qquad ( 11 )$$

Equation (11) is assigned to Equation (7), and thus the following Equation 12 is derived.

$$D = \frac{k \cdot ( R + 1 )}{10 \cdot {log}_{10} ( 1 - α ) \cdot {log}_{10} ( R )} \qquad ( 12 )$$

According to Equation (12), Equation (3) is required to be satisfied so that the attenuation rate α is 1%/m or less. Equation (3) is derived under the conditions that the frequency F of a microwave is 2,500 MHz, the conductivity ρ of the inner conductor and the outer conductor of the coaxial tube made of aluminum is 2.65×10⁸ Ω·m, and each of the relative permittivity εᵣ and the permeability p of the medium between the inner conductor and the outer conductor of the coaxial tube is 1.

In FIG. 5, a curve indicated by (3) indicates a boundary of a range of a set of the diameter d and the diameter D satisfying the Equation (3). Here, a characteristic impedance Z₀ of the coaxial tube is expressed by the following Equation (13).

$${Z}_{0} = \sqrt{\frac{ɛ}{μ}} \cdot \frac{1}{2 π} \cdot ln \frac{D}{d} \qquad ( 13 )$$

In Equation (13), ε is a permittivity of the medium between the inner conductor and the outer conductor of the coaxial tube. When the medium between the inner conductor and the outer conductor of the coaxial tube is vacuum or air, ε is 8.85×10⁻¹², and μ is 4π×10−7. Therefore, when the medium between the inner conductor and the outer conductor of the coaxial tube is vacuum or air, the following Equation (14) is derived from Equation (13).

$$R = \frac{D}{d} = {e}^{\frac{{Z}_{0}}{60}} \qquad ( 14 )$$

In FIG. 5, a curve indicated by (3) is derived by using a value obtained by assigning R to Equation (3) and the relationship of d=D/R, R being obtained by using Z₀ in Equation (14) as a variable.

In FIG. 5, a range of a set of the diameter d and the diameter D satisfying Equations (1), (2), and (3) is indicated by a hatched region. The coaxial waveguide 21 may employ, as the one or more coaxial tubes, a coaxial tube having a set of the diameter d and the diameter D in the hatched region in FIG. 5.

In an embodiment, the characteristic impedance of the coaxial waveguide 21 may be values other than 50Ω. As can be seen from Equation (14), in the hatched region in FIG. 5, the number of options of sets of the diameter d of the inner conductor and the diameter D of the outer conductor having the characteristic impedance of 50Ω is limited. Therefore, the coaxial waveguide 21 having characteristic impedances of values other than 50Ω is used, and thus the degree of freedom of design of the one or more coaxial tubes can be increased.

Hereinafter, discharge power of the coaxial tube will be discussed. Discharge power P_{S} is expressed by the following Equation (15).

$${P}_{S} = \frac{{( {E}_{S} \cdot \frac{D - d}{2} )}^{2}}{8 \times {Z}_{0}} \qquad ( 15 )$$

In Equation (15), E_{S} is a discharge electric field. It is necessary to satisfy Equation (16) derived from Equation (15) so that the discharge power P_{S} is equal to or more than a designated value P_{SS}.

$$d \leq D - \frac{4 \times \sqrt{2 \times {Z}_{0} \times {P}_{SS}}}{{E}_{S}} \qquad ( 16 )$$

In FIG. 5, a straight line indicated by (16) indicates a boundary of a range of a set of the diameter d and the diameter D satisfying the Equation (16) when the discharge electric field E_{S} is 0.334 kV/mm, and the designated value P_{SS} is 10 kW. As is clear from FIG. 5, when Equations (1), (2), and (3) are satisfied, Equation (16) is automatically satisfied.

While various exemplary embodiments have been described above, various omissions, substitutions and changes may be made without being limited to the exemplary embodiments described above. Elements of the different embodiments may be combined to form another embodiment.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber;
a microwave generator;
an antenna configured to radiate a microwave into the chamber; and
a coaxial waveguide configured to cause a microwave output from the microwave generator to propagate between the microwave generator and the antenna,
wherein a diameter d of an outer circumferential surface of an inner conductor and a diameter D of an inner circumferential surface of an outer conductor of each of one or more coaxial tubes configuring the coaxial waveguide satisfy the following Equations (1), (2), and (3):
$$\begin{matrix}D + d \leq 76.3 [ mm ] & ( 1 ) \\ d \geq 21 [ mm ] & ( 2 ) \\ D \geq 3.71 \times \frac{( R + 1 )}{{log}_{10} ( R )} & ( 3 )\end{matrix}$$
where R is D/d.

2. The plasma processing apparatus according to claim 1,
wherein the microwave generator and the antenna are connected to each other via only the coaxial waveguide.

3. The plasma processing apparatus according to claim 1,
wherein a characteristic impedance of the coaxial waveguide is a value other than 50Ω.
